(19) United States
(12) Patent Application Publication
(10) Pub. No.: US 2009/0289689 A1
(43) Pub. Date: Nov. 26, 2009

(54) Signal output circuit and selector circuit using the same

(75) Inventor: Yasuhiro Takai, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: Elpida Memory, Inc., Tokyo (JP)

(21) Appl. No.: 12/453,738

(22) Filed: May 20, 2009

(30) Foreign Application Priority Data
May 22, 2008 (JP) P2008-134776

(51) Int. Cl. H03K 17/00

(52) U.S. Cl. 327/407; 327/365

(57) ABSTRACT

A signal output circuit adapted to a selector circuit is constituted of an inverter circuit which activates propagation of an input signal therethrough in an active level of a control signal and which inactivates it in an inactive level of the control signal, and a control circuit which maintains the input terminal of the inverter circuit at a predetermined potential irrespective of the level of the input signal in the inactive level of the control signal. This achieves high-speed and high-precision propagation of the input signal. The selector circuit is formed using a plurality of signal output circuits so as to selectively output one of first and second input signals in response to the control signal.

### BACKGROUND OF THE INVENTION

1. Field of the Invention

The present invention relates to signal output circuits for selectively outputting input signals thereof. The present invention also relates to selector circuits using signal output circuits.

The present application claims priority on Japanese Patent Application No. 2008-134776, the content of which is incorporated herein by reference in the entirety.

2. Description of the Related Art

Conventionally, clocked inverter circuits serve as signal output circuits for selectively outputting input signals thereof. FIG. 5 shows an example of a clocked inverter circuit, which includes a CMOS inverter constituted of a P-channel MOS transistor (denoted as a PMOS transistor) 51 and an N-channel MOS transistor (denoted as an NMOS transistor) 52.

The clocked inverter circuit of FIG. 5 further includes a PMOS transistor 50 connected between the PMOS transistor 51 and a VDD power-supply line, an NMOS transistor 53 connected between the source of the NMOS transistor 52 and the ground, an inverter 54 for inverting the phase of an input signal IN1 at an input terminal 500 and for supplying it to the CMOS inverter, and an inverter 55 for inverting the phase of a select signal SEL1 at an input terminal 501.

The select signal SEL1 is directly supplied to the gate of the NMOS transistor 53, while the select signal SEL1 is inverted by the inverter 55 and is then supplied to the gate of the PMOS transistor 50.

When the select signal SEL1 reaches a high level, both the PMOS transistor 50 and the NMOS transistor 53 are turned on so that the supply voltage VDD is applied to the CMOS inverter (including the PMOS transistor 51 and the NMOS transistor 52), which is thus activated.

Due to the activation of the CMOS inverter, the input signal IN1 is output to an output terminal 502 by way of the inverter 54 and the CMOS inverter.

When the select signal SEL1 reaches a low level, both the PMOS transistor 50 and the NMOS transistor 53 are turned off, so that the output terminal 502 is disconnected from the power-supply line of VDD and the ground and is thus placed at high impedance irrespective of the level of the input signal IN1.

FIG. 6 shows another example of a clocked inverter circuit, in which PMOS transistors 60 and 61 and NMOS transistors 62 and 63 are connected in series between a power-supply line of VDD and the ground. The gate of the PMOS transistor 60 is connected to the gate of the NMOS transistor 63. An input signal IN1 at an input terminal 600 is supplied to the gates of the transistors 60 and 63 via an inverter 64.

The drain of the PMOS transistor 61 and the drain of the NMOS transistor 62 are connected to an output terminal 602. A select signal SEL1 at an input terminal 601 is directly supplied to the gate of the NMOS transistor 62, while it is inverted by an inverter 65 and is then supplied to the gate of the PMOS transistor 61.

When the select signal SEL reaches a high level, both the PMOS transistor 61 and the NMOS transistor 62 are turned on, so that the supply voltage VDD is applied to a CMOS inverter including the transistors 60 and 63, which is thus activated.

Due to the activation of the CMOS inverter, the input signal IN1 at the input terminal 600 is output to the output terminal 602 by way of the inverter 64 and the CMOS inverter.

When the select signal SEL1 reaches a low level, both the PMOS transistor 61 and the NMOS transistor 62 are turned off, so that the output terminal 602 is disconnected from the power-supply line of VDD and the ground and is thus placed at high impedance.

FIG. 7 shows an example of a selector circuit using two sets of clocked inverter circuits shown in FIG. 5, the output terminals of which are connected together so as to selectively output one of two input signals IN1 and IN2 in response to a select signal SEL1.

Specifically, PMOS transistors 70 and 71 and NMOS transistors 72 and 73 are connected in series between a power-supply line of VDD and the ground, wherein a CMOS inverter is formed using the transistors 71 and 72, the gates of which are connected together.

The input signal IN1 at an input terminal 700 is supplied to the CMOS inverter (including the transistors 71 and 72) via an inverter 78-1.

In addition, PMOS transistors 74 and 75 and NMOS transistors 76 and 77 are connected in series between the power-supply line of VDD and the ground, wherein a CMOS inverter is formed using the transistors 75 and 76, the gates of which are connected together.

The input signal IN2 at an input terminal 702 is supplied to the CMOS inverter (including the transistors 75 and 76) via an inverter 78-3.

The output terminal of the CMOS inverter including the transistors 71 and 72 is connected to the output terminal of the CMOS inverter including the transistors 75 and 76, thus forming an output terminal 703.

The select signal SEL1 at an input terminal 701 is supplied to the gate of the NMOS transistor 73 and the gate of the PMOS transistor 74, while it is inverted by an inverter 78-2 and is then supplied to the gate of the PMOS transistor 70 and the gate of the NMOS transistor 77.

The selector circuit of FIG. 7 switches over the input signals IN1 and IN2 in response to the select signal SEL1, thus outputting an output signal OUT at the output terminal 703.

The “propagating” transistors 71, 72, 75, and 76 used for propagating the input signals IN1 and IN2 are connected inside of the output terminal 703, while the “blocking” transistors 70, 73, 74, and 77 used for blocking the input signals IN1 and IN2 are connected outside of the output terminal 703.

When the select signal SEL1 reaches a high level, the blocking transistors 70 and 73 are turned on while the other blocking transistors 74 and 77 are turned off, thus allowing the input signal IN1 to selectively propagate to the output terminal 703 as the output signal OUT.

Since the gate capacities and drain-diffusion-layer capacities of the blocking transistors 70 and 73 both turned on are already charged and discharged at the supply voltage VDD and the ground level, it is necessary to charge and discharge the gate capacity of the transmitting transistor 71 or 72 and the parasitic capacity occurring at the output terminal 703. This demonstrates an advantage in that the input signal IN1 selectively propagates at high speed.

In the above, a certain level of the input signal IN2 which is not selected at present may vary the potential of a node N2 (corresponding to the output terminal of the inverter 78-3) so as to turn on one of the propagating transistors 75 and 76, which is thus connected to the output terminal 703 so as to form a parasitic capacity.

Generally speaking, the mobility of a PMOS transistor is lower than the mobility of an NMOS transistor; hence, in a clocked inverter circuit including a PMOS transistor and an NMOS transistor, the gate width of the PMOS transistor must be PN times (where PN ranges from “2” to “3”) larger than the gate width “W” of the NMOS transistor, i.e. PN×W. Depending upon the level of the “non-selected” input signal IN2, one of the PMOS transistor 75 and the NMOS transistor 76 which have different gate capacities is turned on so as to vary the propagation time for the “selected” input signal IN1.

When the input signal IN1 presently selected propagates from the input terminal 701 to the output terminal 703 simultaneously with potential variations of the node N2 occurring due to the level transition of the non-selected input signal IN2, the gate capacities of the transistors 75 and 76 are coupled due to potential variations of the node N2 so as to form a coupling noise, which is convoluted at the output terminal 703, thus deforming the signal waveform appearing at the output terminal 703.

That is, the level transition of the non-selected input signal IN2 varies the propagation time of the selected input signal IN1 propagating from the input terminal 700 to the output terminal 703, thus degrading a propagation precision. When the selector circuit is applied to a DLL or PLL, such a low propagation precision causes output jitters.

FIG. 8 shows another example of a selector circuit which is designed to focus on the propagation precision of an input signal and which is formed using two sets of the clocked inverter circuit of FIG. 6, the output terminals of which are connected together so as to selectively output one of input signals IN1 and IN2 in response to a select signal SEL1.

Specifically, PMOS transistors 80 and 81 and NMOS transistors 82 and 83 are connected in series between a power-supply line of VDD and the ground, wherein a CMOS inverter is formed using the transistors 80 and 83 whose gates are connected together.

The input signal IN1 at an input terminal 800 is supplied to the input terminal of the CMOS inverter including the transistors 80 and 83 via an inverter 88-1.

In addition, PMOS transistors 84 and 85 and NMOS transistors 86 and 87 are connected in series between the power-supply line VDD and the ground, wherein a CMOS inverter is formed using the transistors 84 and 87 whose gates are connected together.

The input signal IN2 at an input terminal 802 is supplied to the input terminal of the CMOS inverter including the transistors 84 and 87.

The output terminal of the CMOS inverter including the transistors 80 and 83 is connected to the output terminal of the CMOS inverter including the transistors 84 and 87, thus forming an output terminal 803.

The select signal SEL1 at an input terminal 801 is directly supplied to the gate of the NMOS transistor 82 and the gate of the PMOS transistor 85, while it is inverted by an inverter 88-2 and is then supplied to the gate of the PMOS transistor 81 and the gate of the NMOS transistor 86.

The selector circuit of FIG. 8 switches over the input signals IN1 and IN2 so as to output an output signal OUT at the output terminal 803 in response to the select signal SEL1.

In contrast to the selector circuit of FIG. 7, the selector circuit of FIG. 8 is designed such that the “propagating” transistors 80, 83, 84, and 87 used for propagating the input signals IN1 and IN2 are connected outside of the output terminal 803, while the “blocking” transistors 81, 82, 85, and 86 used for blocking the input signals IN1 and IN2 are connected inside of the output terminal 803.

When the select signal SEL1 reaches a high level, both the blocking transistors 81 and 82 are turned on while the other blocking transistors 85 and 86 are turned off, thus allowing the input signal IN1 to selectively propagate to the output terminal 803 as the output signal OUT.

Since the blocking transistors 85 and 86 when both turned off are connected inside of the output terminal 803, the level transition of the non-selected input signal IN2 does not affect the output signal OUT at the output terminal 803, wherein the propagation time of the selected input signal IN1 propagating from the input terminal 800 to the output terminal 803 is maintained constant, thus securing a high propagation precision.

During the propagation of the selected input signal IN1 propagating from the input terminal 800 to the output terminal 803, it is necessary to charge and discharge the gate capacity of the propagating transistor 80 or 83 while further charging and discharging the gate capacity of the blocking transistor 81 or 82, thus decreasing the propagation speed for the selected input signal IN1.

It is possible to increase the propagation speed by increasing the gate widths of the transistors and thus increasing their drive capabilities, thus proportionally increasing the gate capacities subjected to charging and discharging; hence, the effect is limited. In particular, when the selector circuit is applied to the circuitry, such as DLL and PLL, which operate at high speed and with low voltage so as to reduce power consumption, the selected input signal may not propagate in a rail-to-rail manner due to a low charging/discharging speed, thus increasing deviations of duty cycles and thus causing output jitters.

In consideration of the above circumstances, various technologies have been developed and disclosed in various documents such as Patent Documents 1 to 3.
Patent Document 1: Japanese Unexamined Patent Application Publication No. H05-315922
Patent Document 2: Japanese Unexamined Patent Application Publication No. H11-136112
Patent Document 3: Japanese Unexamined Patent Application Publication No. 2006-157286

Patent Document 1 teaches a CMOS semiconductor integrated circuit including a signal select circuit constituted of a switching circuit and a control circuit. The switching circuit includes a plurality of CMOS transfer gates whose first terminals are connected to respective input terminals and whose second terminals are all connected to a single output terminal. The control circuit controls the switching circuit such that two or more CMOS transfer gates are not simultaneously turned on based on combinations of logics of output control signals for controlling the output signal of the switching circuit.

Patent Document 2 teaches a logic circuit including MOS transistors and serving as a selector.

Patent Document 3 teaches a selector circuit for selectively outputting one of input signals.

The CMOS semiconductor integrated circuit of Patent Document 1 is designed to minimize the signal propagation time of a selected signal propagating from the input terminal to the output terminal, thus improving the operation speed.

The logic circuit of Patent Document 2 serving as the selector circuit is designed to reduce an on-resistance lying between the output terminal and the high-potential power supply so as to reduce the parasitic capacity occurring at the output terminal, thus securing high-speed operation.

The selector circuit of Patent Document 3 is designed to suppress the rust of a signal waveform and a propagation delay of a selected signal by reducing a load capacity.

The present inventor has recognized that all the above technologies disclosed in Patent Documents 1 to 3 merely aim at increasing the signal propagation speed, but do not consider the improvement of the signal propagation precision.

### SUMMARY

The invention seeks to solve the above problem, or to improve upon the problem at least in part.

In one embodiment of the present invention, a signal output circuit is constituted of an inverter circuit which receives a gate signal and a control signal and which allows the gate signal to propagate therethrough in an active level of the control signal while blocking the input signal in an inactive level of the control signal, and a control circuit which maintains the input terminal of the inverter circuit at a predetermined potential irrespective of the level of an input signal in the inactive level of the control signal.

In another embodiment of the present invention, a selector circuit is constituted of a first inverter circuit which receives a first input signal and a first control signal and which activates propagation of the first input signal therethrough in an active level of the first control signal while inactivating it in an inactive level of the first control signal, a second inverter circuit which receives a second input signal and a second control signal and which activates propagation of the second input signal therethrough in an active level of the second control signal while inactivating it in an inactive level of the second control signal, and a control circuit which maintains the input terminal of the first inverter circuit at a predetermined potential irrespective of the level of the first input signal in the inactive level of the first control signal and which maintains the input terminal of the second inverter circuit at the predetermined potential irrespective of the level of the second input signal in the inactive level of the second control signal.

The present invention demonstrates the following effects.
(1) In the signal output circuit, the control circuit includes a transistor which is connected in series with the inverter circuit in connection with the power-supply line or the ground, wherein the transistor is charged by the power-supply line or discharged to the ground in advance. Thus, it is possible to achieve high-speed and high-precision propagation of the input signal propagating from the input terminal to the output terminal because it is only necessary to simply charge and discharge the gate capacities of transistors included in the inverter circuit and the parasitic capacity at the output terminal.
(2) In the selector circuit, one of the first and second control signals is placed in the active level while the other is placed in the inactive level, wherein one of the first and second input signals is selected and output to the output terminal. Since the level transition of the non-selected input signal does not affect the potential at the output terminal, it is possible to fix the propagation time of the selected input signal. Thus, it is possible to achieve high-speed and high-precision propagation with respect to the selected input signal.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a circuit diagram showing the constitution of a signal output circuit according to a first embodiment of the present invention;

FIG. 2 is a circuit diagram showing the constitution of a signal output circuit according to a second embodiment of the present invention;

FIG. 3 is a circuit diagram showing the constitution of a selector circuit according to a third embodiment of the present invention;

FIG. 4 is a circuit diagram showing the constitution of a selector circuit according to a fourth embodiment of the present invention;

FIG. 5 is a circuit diagram showing an example of the aforementioned clocked inverter circuit;

FIG. 6 is a circuit diagram showing another example of the foregoing clocked inverter circuit;

FIG. 7 is a circuit diagram showing an example of the foregoing selector circuit;

FIG. 8 is a circuit diagram showing another example of the foregoing selector circuit; and

FIG. 9 is a circuit diagram showing the constitution of a selector circuit according to a fifth embodiment of the present invention.

### DETAILED DESCRIPTION OF PREFERRED EMBODIMENTS

The present invention will be now described herein with reference to illustrative embodiments. Those skilled in the art will recognize that many alternative embodiments can be accomplished using the teachings of the present invention and that the invention is not limited to the embodiments illustrated for explanatory purposes.

The present invention is basically directed to a signal output circuit having a clocked inverter circuit which operates based on a plurality of input signals and at least one control signal, wherein the signal output circuit is activated at an active level of the control signal but is inactivated at an inactive level of the control signal. The signal output circuit of the present invention includes a control circuit for maintaining a predetermined potential at a prescribed node irrespective of levels of input signals.

### 1. First Embodiment

FIG. 1 shows a signal output circuit according to a first embodiment of the present invention, which is constituted of a CMOS inverter including a PMOS transistor 10 and an NMOS transistor 11, and a control circuit including an NMOS transistor 12 and a NAND gate 13 receiving an input signal IN1 and a select signal SEL1. The source of the PMOS transistor 10 is connected to a power-supply line (whose supply voltage VDD is referred to as a first level), and the drain thereof is connected to an output terminal 102, and the gate thereof is connected to the gate of the NMOS transistor 11. The drain of the NMOS transistor 12 is connected to the source of the NMOS transistor 11, the source thereof is connected to the ground (the ground potential VSS of which is referred to as a second level), and the gate thereof receives a select signal SEL1 serving as a control signal. The NAND gate 13 performs a NAND operation based on the input signal IN1 and the select signal SEL1, wherein the result of the NAND operation is supplied to the CMOS inverter. In FIG. 1, a clocked inverter circuit is formed using the PMOS transistor 10 and the NMOS transistors 11 and 12.

When the select signal SEL1 at an input terminal 101 reaches a low level (or an inactive level), the NMOS transistor 12 is turned off so that the output potential of the NAND gate 13 is maintained at a high level, whereby the PMOS transistor 10 is turned off so as to disconnect the supply voltage VDD from the CMOS inverter, which is thus inactivated. In this state, even when the input signal IN1 at an input terminal 100 is supplied to the CMOS inverter via the NAND gate 13, the CMOS inverter does not perform the switching operation on the input signal IN1.

When the select signal SEL1 reaches a high level (or an active level), the NMOS transistor 12 is turned on so that the supply voltage VDD is supplied to the CMOS inverter including the transistors 10 and 11. In this state, the CMOS inverter is activated so that the input signal IN1 propagates toward the output terminal 102 via the NAND gate 13 and the CMOS inverter.

In the above, the NMOS transistor serving as a switch is connected in series with the CMOS inverter and is discharged at the ground potential VSS in advance, wherein it is necessary to simply charge and discharge the gate capacities of the transistors 10 and 11 (included in the CMOS inverter) and the parasitic capacity at the output terminal 102 during the propagation of the input signal IN1 from the input terminal 100 to the output terminal 102. This achieves high-speed propagation of the input signal IN1.

### 2. Second Embodiment

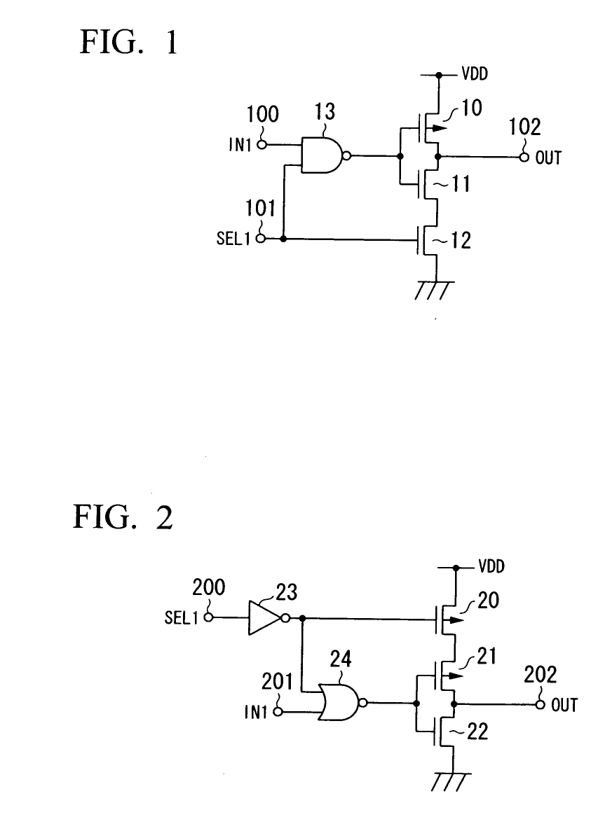

FIG. 2 shows a signal output circuit according to a second embodiment of the present invention, which is constituted of a CMOS inverter including a PMOS transistor 21 and an NMOS transistor 22, and a control circuit including a PMOS transistor 20, an inverter 23, and a NOR gate 24. The drain of the PMOS transistor 21 is connected to an output terminal 202. The drain of the NMOS transistor 22 is connected to the drain of the PMOS transistor 21, the gate thereof is connected to the PMOS transistor 21, and the source thereof is connected to the ground (having the ground potential VSS). The source of the PMOS transistor 20 is connected to a power-supply line (having the supply voltage VDD), and the drain thereof is connected to the source of the PMOS transistor 21. The inverter 23 inverts the select signal SEL1 (serving as a control signal) so as to output an inverted select signal to the gate of the PMOS transistor 20. The NOR gate 24 performs a NOR operation based on the inverted select signal (output from the inverter 23) and an input signal IN1 at an input terminal 201, so that the result of the NOR operation is supplied to the CMOS inverter. In this connection, a clocked inverter circuit is formed using the PMOS transistors 20 and 21 and the NMOS transistor 22.

When the select signal SEL1 at an input terminal 200 reaches a low level (or an inactive level), the PMOS transistor 20 is turned off so that the output potential of the NOR gate 24 is maintained at a low level, wherein the NMOS transistor 22 is turned off so as to disconnect the supply voltage VDD to the CMOS inverter. In this state, the CMOS inverter is inactivated so as not to perform the switching operation on the input signal IN1 even when the input signal IN1 is supplied to the CMOS inverter via the NOR gate 24.

When the select signal SEL reaches a high level (or an active level), the PMOS transistor 20 is turned on so that the supply voltage VDD is supplied to the CMOS inverter including the transistors 21 and 22. In this state, the CMOS inverter is activated so that the input signal IN1 propagates from the input terminal 201 to the output terminal 202 via the NOR gate 24 and the CMOS inverter.

In the above, the PMOS transistor 20 serving as a switch is connected in series with the CMOS inverter and is charged at the supply voltage VDD in advance, wherein it is necessary to simply charge and discharge the gate capacities of the transistors 21 and 22 (included in the CMOS inverter) and the parasitic capacity at the output terminal 202 during the propagation of the input signal IN1 from the input terminal 201 to the output terminal 202. This achieves high-speed propagation of the input signal IN1.

### 3. Third Embodiment

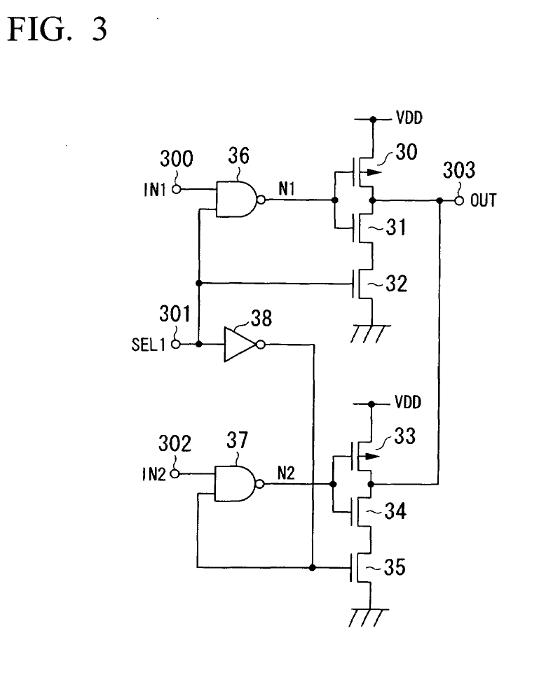

FIG. 3 shows a selector circuit according to a third embodiment of the present invention, which is formed using two sets of the signal output circuit of FIG. 1, the output terminals of which are connected together so as to selectively output one of input signals IN1 and IN2 at input terminals 300 and 302 in response to a select signal SEL1 at an input terminal 301.

That is, the selector circuit of FIG. 3 includes a first signal select circuit (including a first CMOS inverter) and a second signal output circuit (including a second CMOS inverter), which are connected together via an inverter 38 which inverts the select signal SEL1 so as to output an inverted select signal.

Specifically, the first CMOS inverter is constituted of a PMOS transistor 30, in which the source is connected to a power-supply line (whose supply voltage VDD is referred to as a first level) and the drain is connected to an output terminal 303, and an NMOS transistor 31, in which the drain is connected to the drain of the PMOS transistor 30 and the gate is connected to the gate of the PMOS transistor 30. The first CMOS inverter is connected in series with a NMOS transistor 32, in which the drain is connected to the source of the NMOS transistor 31, the source is connected to the ground (whose ground level VSS is referred to as a second level), and the gate receives the select signal SEL1. A NAND gate 36 performs a NAND operation on the input signal IN1 and the select signal SEL1 so as to output the result of the NAND operation to the first CMOS inverter.

The second CMOS inverter is constituted of a PMOS transistor 33, in which the source is connected to the power-supply line of VDD and the drain is supplied to the output terminal 303, and an NMOS transistor 34, in which the drain is connected to the drain of the PMOS transistor 33 and the gate is connected to the gate of the PMOS transistor 33. The second CMOS inverter is connected in series with an NMOS transistor 35, in which the drain is connected to the source of the NMOS transistor 34, the source is connected to the ground, and the gate receives the inverted select signal output from the inverter 38. A NAND gate 37 performs a NAND operation on the input signal IN2 and the inverted select signal so as to output the result of the NAND operation to the second CMOS inverter.

When the select signal SEL1 reaches a high level (or an active level), the NAND gate 36 allows the input signal IN1, which is presently selected, to propagate to a node N1 (corresponding to the output terminal of the NAND gate 36). In this state, the NMOS transistor 32 is turned on so as to activate the first CMOS inverter (including the transistors 30 and 31), thus allowing the input signal IN1 to propagate to the output terminal 303 as an output signal OUT.

Since the NAND gate 37 receives the inverted select signal, the potential at a node N2 (corresponding to the output terminal of the NAND gate 37) is fixed at a high level. In this state, the PMOS transistor 33 is turned off while the NMOS transistor 35 whose gate receives the inverted select signal is turned off, so that the level transition of the input signal IN2, which is not selected at present, does not affect the potential at the output terminal 303.

Since the gate capacity and drain-diffusion-layer capacity of the NMOS transistor 32 is discharged at the ground potential VSS in advance, it is necessary to simply charge and discharge the gate capacity of the transistor 30 or 31 (included in the first CMOS inverter) and the parasitic capacity at the output terminal 303 during the propagation of the selected input signal IN1 from the input terminal 300 to the output terminal 303. This achieves high-speed propagation of the input signal IN1.

Since the level transition of the non-selected input signal IN2 does not affect the potential of the output terminal 303, it is possible to secure the “constant” propagation time for the selected input signal IN1 propagating from the input terminal 300 to the output terminal 303, thus achieving a high propagation precision with respect to the selected input signal IN1. In conclusion, the selector circuit of FIG. 3 achieves high-speed and high-precision propagation with respect to the selected input signal.

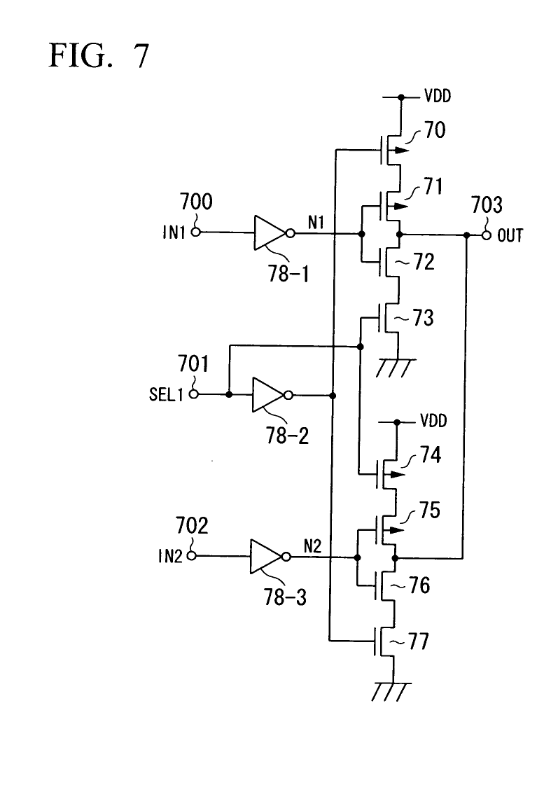

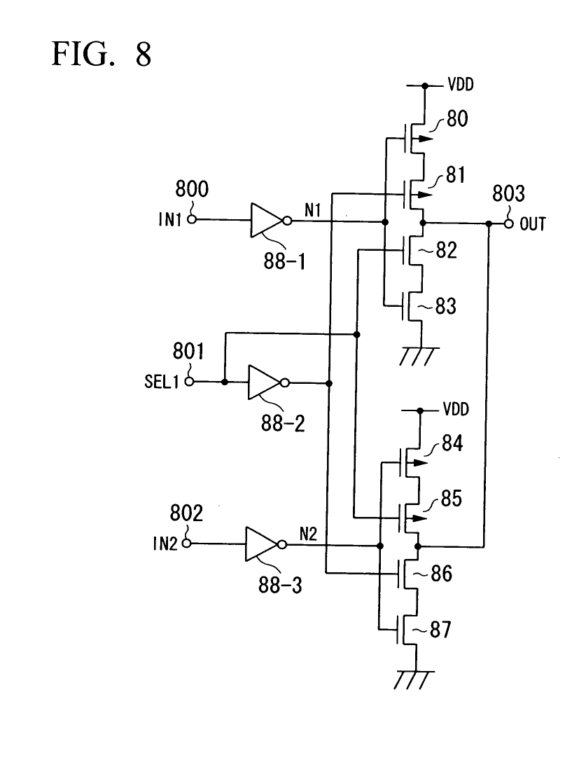

In the foregoing selector circuits shown in FIGS. 7 and 8, the gate width of the PMOS transistor is PN times larger than the gate width W of the NMOS transistor, i.e. PN×W, in order to secure the same drive ability between the PMOS and NMOS transistors. In the selector circuit of FIG. 3, the PMOS transistor is not placed in a cascade connection with the NMOS transistor; hence, it is sufficient that the gate width of the PMOS transistor be set to PN×W/2 in order to secure the same drive ability with the NMOS transistor.

Specifically, it is sufficient that the gate capacity and drain-diffusion-layer capacity of the PMOS transistor 30 (included in the first CMOS inverter used for the propagation of the selected input signal SEL1) be reduced to approximately half the foregoing ones while the drain-diffusion-layer capacity of the PMOS transistor 33 (included in the second CMOS inverter adapted to the non-selected input signal IN2) be reduced to approximately half the foregoing one. Thus, it is possible to charge and discharge the PMOS transistors 30 and 33 in the selector circuit of FIG. 3 compared to the foregoing selector circuits.

The path from the input terminal 300 to the node N1 and the path from the node N1 to the output terminal 303 are each associated with a cascode connection including one PMOS transistor and two NMOS transistors. This sustains the advantage of the foregoing selector circuits in which the leading-edge propagation occurs symmetrically with the trailing-edge propagation with respect to the selected input signal.

### 4. Fourth Embodiment

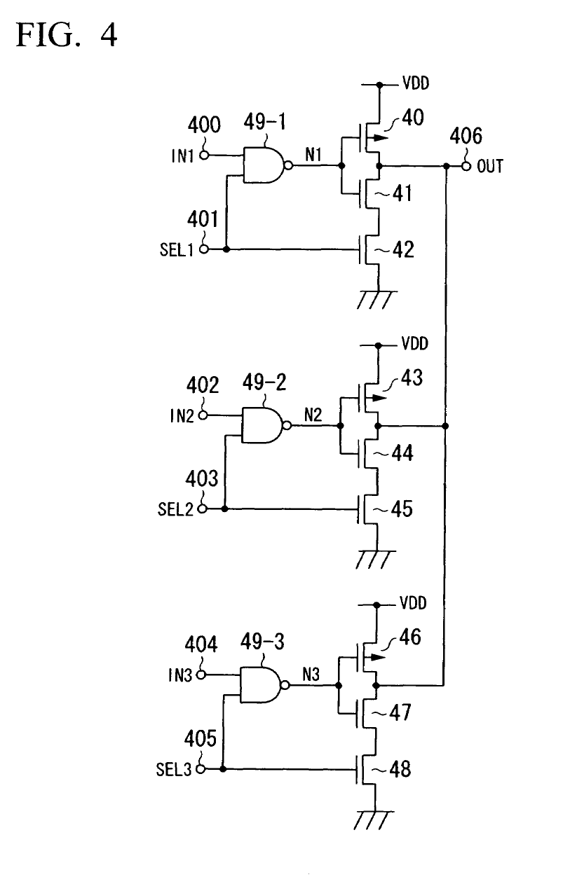

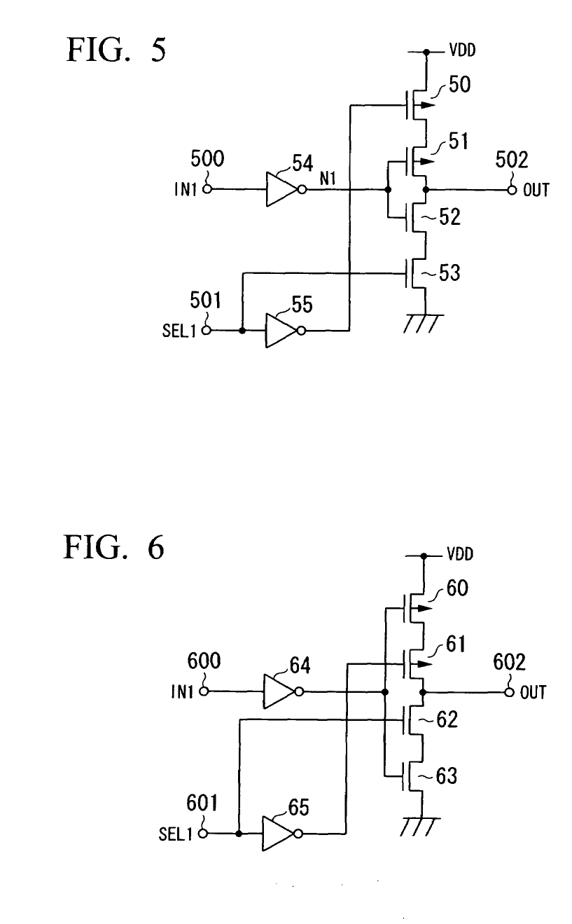

FIG. 4 shows a selector circuit according to a fourth embodiment of the present invention, which is constituted of three sets of the signal output circuit of FIG. 1, namely, first, second, and third signal output circuits whose output terminals are connected together and which receive respective control signals, one which is activated while other control signals are inactivated. Since these signal output circuits has the same constitution as the signal output circuit of FIG. 1, the detailed descriptions thereof are omitted or simplified as necessary.

The first signal output circuit is constituted of a first CMOS inverter including a PMOS transistor 40 and an NMOS transistor 41, an NMOS transistor 42 which is connected between the first CMOS inverter and the ground, and a NAND gate 49-1. The NAND gate 49-1 receives an input signal IN1 at an input terminal 400 and a select signal SEL1 at an input terminal 401. The select signal SEL1 is supplied to the gate of the NMOS transistor 42.

The second signal output circuit is constituted of a second CMOS inverter including a PMOS transistor 43 and an NMOS transistor 44, an NMOS transistor 45 which is connected between the second CMOS inverter and the ground, and a NAND gate 49-2. The NAND gate 49-2 receives an input signal IN2 at an input terminal 402 and a select signal SEL2 at an input terminal 403. The select signal SEL2 is supplied to the gate of the NMOS transistor 45.

The third signal output circuit is constituted of a third CMOS inverter including a PMOS transistor 46 and an NMOS transistor 47, an NMOS transistor 48 which is connected between the third CMOS inverter and the ground, and a NAND gate 49-3. The NAND gate 49-3 receives an input signal IN3 at an input terminal 404 and a select signal SEL3 at an input terminal 405. The select signal SEL3 is supplied to the gate of the NMOS transistor 48.

One of the select signals SEL1, SEL2, and SEL3 is placed at a high level (or an active level), while other select signals are each placed at a low level (or an inactive level).

When one of the select signals SEL1, SEL2, and SEL3 reaches a high level, one of the input signals IN1, IN2, and IN3 is correspondingly selected and output to an output terminal 406 as an output signal OUT.

The selector circuit of FIG. 4 is basically similar to the selector circuit of FIG. 3 in terms of the constitution and operation except that, in contrast to the selector circuit of FIG. 3 for selectively outputting one of the two input signals IN1 and IN2 in response to the select signal SEL1, the selector circuit of FIG. 4 is designed to selectively output one of the three input signals IN1, IN2, and IN3 in response to the three select signals SEL1, SEL2, and SEL3 independently applied to the three signal output circuits.

The selector circuit of FIG. 4 has similar characteristics and effects as the selector circuit of FIG. 3. Thus, the selector circuit of FIG. 4 achieves high-speed and high-precision propagation with respect to the selected input signal.

### 5. Fifth Embodiment

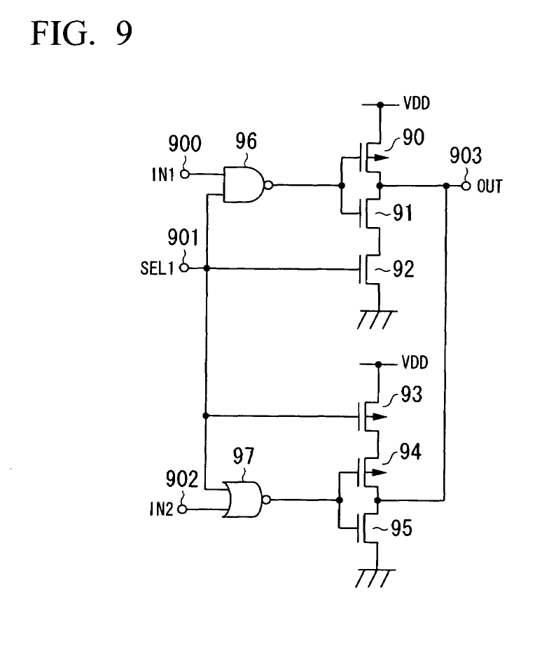

FIG. 9 shows a selector circuit according to a fifth embodiment of the present invention, which is created by partially modifying the selector circuit of FIG. 3. That is, the selector circuit of FIG. 9 is designed to exclude the inverter 38 from the selector circuit of FIG. 3, wherein it is constituted of a first signal output circuit (including a first clocked inverter circuit) and a second signal output circuit (including a second clocked inverter circuit). In the selector circuit of FIG. 9, the first signal output circuit is formed such that a first CMOS inverter is connected in series with a first conduction-type MOS transistor (e.g. an NMOS transistor) between the power-supply line (whose supply voltage VDD is referred to as a first level) and the ground (whose ground potential is referred to as a second level), while the second signal output circuit is formed such that a second CMOS inverter is connected in series with a second conduction-type MOS transistor (e.g. a PMOS transistor), wherein the select signal SEL1 is directly supplied to the gate of the first conduction-type MOS transistor and the gate of the second conduction-type MOS transistor, and wherein the NAND gate 37 shown in FIG. 3 is replaced with a NOR gate 97 whose output terminal is connected to the input terminal of the second CMOS inverter and which receives the input signal IN2 and the select signal SEL1 (serving as a control signal).

Specifically, the first CMOS inverter is constituted of a PMOS transistor 90 whose source is connected to the power-supply line of VDD and whose drain is connected to an output terminal 903, and an NMOS transistor 91 whose drain is connected to the drain of the PMOS transistor 90 and whose gate is connected to the gate of the PMOS transistor 90. An NMOS transistor 92 is connected in series with the first CMOS inverter, wherein the drain thereof is connected to the source of the NMOS transistor 91, the source thereof is connected to the ground, and the gate thereof receives the select signal SEL1. A PMOS transistor 93 is connected in series with the second CMOS inverter, wherein the source thereof is connected to the power-supply line of VDD and the gate thereof receives the select signal SEL1. The second CMOS inverter is constituted of a PMOS transistor 94 whose source is connected to the drain of the PMOS transistor 93 and whose drain is connected to the output terminal 903, and an NMOS transistor 95 whose drain is connected to the drain of the PMOS transistor 94, whose gate is connected to the gate of the PMOS transistor 94, and whose source is connected to the ground. A NAND gate 96 performs a NAND operation on the input signal IN1 at an input terminal 900 and the select signal SEL1 at an input terminal 901, thus outputting the result of the NAND operation to the input terminal of the first CMOS inverter. The NOR gate 97 performs a NOR operation on the input signal IN2 at an input terminal 902 and the select signal SEL1, thus outputting the result of the NOR operation to the input terminal of the second CMOS inverter.

When the select signal SEL1 reaches a high level (or an active level), the NAND gate 96 transmits the input signal IN1, which is presently selected, therethrough. Since both the transistors 90 and 92 are turned on so that the first CMOS inverter including the transistors 90 and 91 is activated, the selected input signal IN1 propagates to the output terminal 903 as the output signal OUT via the first CMOS inverter.

The output potential of the NOR gate 97 receiving the “high-level” select signal SEL1 is fixed at a low level so that the NMOS transistor 95 is turned off, wherein the PMOS transistor 93 receiving the high-level select signal SEL1 is turned off. As a result, the level transition of the “non-selected” input signal IN2 does not affect the potential at the output terminal 903.

Since the gate capacity and drain-diffusion-layer capacity of the NMOS transistor 92 are discharged to the ground level VSS in advance, it is necessary to simply charge and discharge the gate capacity of the transistor 90 or 91 (included in the first CMOS inverter) and the parasitic capacity at the output terminal 903 during propagation of the selected input signal IN1 from the input terminal 900 to the output terminal 903. This achieves high-speed propagation with respect to the selected input signal IN1.

Since the level transition of the non-selected input signal IN2 does not affect the potential at the output terminal 903, the “constant” propagation time is secured with respect to the selected input signal IN1 propagating from the input terminal 900 to the output terminal 903; hence, it is possible to achieve high-speed and high-precision propagation with respect to the selected input signal IN1.

Without the inverter 38, it is possible to simplify the constitution of the selector circuit of FIG. 9, thus reducing the manufacturing cost.

Lastly, it is apparent that the present invention is not limited to the above embodiments, but may be further modified and changed without departing from the scope and spirit of the invention.

What is claimed is:

1. A signal output circuit comprising:
an inverter circuit receiving a gate signal and a control signal, wherein the inverter circuit allows the gate signal to propagate therethrough in an active level of the control signal while the inverter circuit blocks the gate signal in an inactive level of the control signal; and
a control circuit maintaining an input terminal of the inverter circuit at a predetermined potential irrespective of a level of an input signal in the inactive level of the control signal.

2. The signal output circuit according to claim 1, wherein the control circuit includes a gate circuit which receives the input signal and the control signal so as to output the gate signal to the input terminal of the inverter via an output terminal thereof, and wherein the output terminal of the gate circuit is maintained at the predetermined potential irrespective of the level of the input signal in the inactive level of the control signal.

3. The signal output circuit according to claim 2, wherein the gate circuit is a NAND gate.

4. The signal output circuit according to claim 2, wherein the gate circuit is a NOR gate.

5. A selector circuit comprising:
a first inverter circuit which receives a first input signal and a first control signal and which activates propagation of the first input signal therethrough in an active level of the first control signal while inactivating it in an inactive level of the first control signal;
a second inverter circuit which receives a second input signal and a second control signal and which activates propagation of the second input signal therethrough in an active level of the second control signal while inactivating it in an inactive level of the second control signal; and
a control circuit which maintains an input terminal of the first inverter circuit at a predetermined potential irrespective of a level of the first input signal in the inactive level of the first control signal and which maintains an input terminal of the second inverter circuit at the predetermined potential irrespective of a level of the second input signal in the inactive level of the second control signal.

6. The selector circuit according to claim 5, wherein the control circuit includes a first gate circuit which receives the first input signal and the first control signal and whose output terminal is connected to the input terminal of the first inverter circuit and a second gate circuit which receives the second input signal and the second control signal and whose output terminal is connected to the input terminal of the second inverter circuit, wherein the output terminal of the first gate circuit is maintained at the predetermined potential irrespective of the level of the first input signal in the inactive level of the first control signal, and wherein the output terminal of the second gate circuit is maintained at the predetermined potential irrespective of the level of the second input signal in the inactive level of the second control signal.

7. The selector circuit according to claim 5, wherein the control circuit includes a first transistor which is arranged between the first inverter circuit and a first level and whose gate receives the first control signal and a second transistor which is arranged between the second inverter circuit and a second level and whose gate receives the second control signal, and wherein the first transistor is turned off in the inactive level of the first control signal while the second transistor is turned off in the inactive level of the second control signal.

8. The selector circuit according to claim 7, wherein a phase of the first control signal is inverse to a phase of the second control signal so that both of the first and second transistors are of a same conduction type.

9. The selector circuit according to claim 7, wherein a phase of the first control signal is identical to a phase of the second control signal so that the first transistor differs from the second transistor in terms of conduction type.

10. The selector circuit according to claim 8, wherein the control circuit further includes a first NAND gate which receives the first input signal and the first control signal and whose output terminal is connected to the input terminal of the first inverter circuit and a second NAND gate which receives the second input signal and the second control signal and whose output terminal is connected to the input terminal of the second inverter circuit.

11. The selector circuit according to claim 9, wherein the control circuit further includes a NAND gate which inputs the first input signal and the first control signal and whose output terminal is connected to the input terminal of the first inverter circuit and a NOR gate which receives the second input signal and the second control signal and whose output terminal is connected to the input terminal of the second inverter circuit.

12. The selector circuit according to claim 5, wherein an output terminal of the first inverter circuit is connected together with an output terminal of the second inverter circuit.

13. A signal output circuit comprising:
a gate circuit which activates propagation of an input signal therethrough in an active level of a control signal and which inactivates it in an inactive level of the control signal, wherein an output signal of the gate circuit is maintained at a prescribed potential irrespective of a level of the input signal in the inactive level of the control signal;
a first transistor coupled with a first level, which is turned off in the inactive level of the control signal;
a second transistor connected in series with the first transistor; and
a third transistor coupled with a second level, whose gate is coupled with a gate of the second transistor so as to receive the output signal of the gate circuit and which is connected in series with the second transistor in connection with an output terminal.

14. The signal output circuit according to claim 13, wherein both the first and second transistors are of a first conduction type, while the third transistor is of a second conduction type.

15. The signal output circuit according to claim 13, wherein the gate circuit is a NAND gate or a NOR gate.

16. The signal output circuit according to claim 13 and adapted to a selector circuit which selectively outputs one of a first input signal and a second input signal as the input signal in response to the control signal.
